(19) United States
(12) Patent Application Publication
(10) Pub. No.: US 2026/0239565 A1
(43) Pub. Date: Aug. 13, 2026

(54) LIQUID-COOLED TYPE HEAT DISSIPATION STRUCTURE

(71) Applicant: ASIA VITAL COMPONENTS CO., LTD., New Taipei City (TW)

(72) Inventors: Chia Hung Lin, New Taipei City (TW); Wen-Ji Lan, New Taipei City (TW)

(21) Appl. No.: 19/062,308

(22) Filed: Feb. 25, 2025

(30) Foreign Application Priority Data
Feb. 7, 2025 (TW) 114104661

(51) Int. Cl. H05K 7/20

(52) U.S. Cl. CPC H05K 7/20272; H05K 7/20263

(57) ABSTRACT

The present invention is a liquid-cooled type heat dissipation structure including at least one liquid cooling heat dissipation module, wherein the liquid cooling heat dissipation module includes two liquid cooling heat dissipation elements for heat conduction in contact with optical modules and one conduit unit; each of the liquid cooling heat dissipation elements is provided with at least one port part; the conduit unit includes a conduit and a pair of seals; each of both ends of the conduit is provided with a connecting part; each of the pair of seals are disposed on the connecting part; the connecting part of the conduit and the seal provided by the conduit unit are used to connect two port parts respectively so as to connect two liquid cooling heat dissipation elements together in series. Therefore, the liquid cooling heat dissipation module can provide liquid cooling heat dissipation for the optical modules.

This application claims the priority benefit of Taiwan patent application number 114104661 filed on Feb. 7, 2025, the disclosure of which is hereby incorporated by reference in its entirety.

### FIELD OF THE INVENTION

The present invention relates to a heat dissipation structure, and more particularly, to a liquid-cooled type heat dissipation structure.

### BACKGROUND OF THE INVENTION

In response to the big data cloud data center transmission solution, the optical module is developed to meet the trend need of the market of the high-speed transmission pluggable solutions. OSFP and QSFP are currently the mainstream of packaging specifications for the high-speed transmission, and their transmission rates can provide bandwidths of up to 400 Gb/s. Although data capacity is maximized, OSFP and QSFP heat dissipation poses huge challenges to their users' operating environment temperature conditions and transmission performance. The heat dissipation of general optical modules cannot be solved simply by air cooling. Therefore, the technical problem of how to solve the problem of heat energy generated by optical modules and how to achieve heat dissipation in an existing environment with a small or limited space (such as a cabinet in a data center) is actually the direction for improvement that the inventor of this case and relevant industry players in this industry urgently want to study.

### SUMMARY OF THE INVENTION

An object of the present invention is to effectively solve the above problem by providing an improved liquid-cooled type heat dissipation structure that can be used in a limited space and is convenient for assembly.

To achieve the above object, the liquid-cooled type heat dissipation structure according to the present invention includes at least one liquid cooling heat dissipation module, wherein the liquid cooling heat dissipation module includes a plurality of liquid cooling heat dissipation elements comprises a plurality of liquid cooling heat dissipation elements with port parts, and a conduit unit used to connect two of the liquid cooling heat dissipation elements in series. The conduit unit includes a conduit and a pair of seals, wherein each of both ends of the conduit is provided with a connecting part and each of the pair of seals is disposed on the connecting part. The connecting part of the conduit and the seal provided by the conduit unit are used to connect two of the port parts respectively so as to connect two of the liquid cooling heat dissipation elements together in series.

Thus, the liquid-cooled type heat dissipation structure of the present invention connects the liquid cooling heat dissipation module through the conduit unit so that the working liquid flows from one liquid cooling heat dissipation element and flows through the conduit unit to another liquid cooling heat dissipation element. The working liquid flows in the liquid cooling heat dissipation element, and the heat energy of the optical module is taken away through the working liquid to achieve the purpose of heat dissipation. Therefore, this liquid-cooled heat dissipation structure can be used to provide liquid cooling heat dissipation for the optical modules of the switch in small or limited spaces such as cabinets (such as data centers).

### BRIEF DESCRIPTION OF THE DRAWINGS

The structure and the technical means adopted by the present invention to achieve the above object can be best understood by referring to the following detailed description of the preferred embodiments and the accompanying drawings, wherein

FIG. 1 is a three-dimensional exploded schematic diagram of the liquid-cooled type heat dissipation structure of the present invention;

FIG. 2 is a three-dimensional exploded schematic diagram of the liquid-cooled type heat dissipation structure of the present invention from another angle;

FIG. 3 is a three-dimensional combined appearance schematic diagram of the liquid-cooled type heat dissipation structure of the present invention;

FIG. 4 is a cross-sectional schematic diagram of the conduit unit in the liquid-cooled type heat dissipation structure of the present invention;

FIG. 5 is a partial cross-sectional schematic diagram of the liquid-cooled type heat dissipation structure of the present invention.

### DETAILED DESCRIPTION OF THE PREFERRED EMBODIMENTS

The present invention will now be described with some preferred embodiments thereof and by referring to the accompanying drawings.

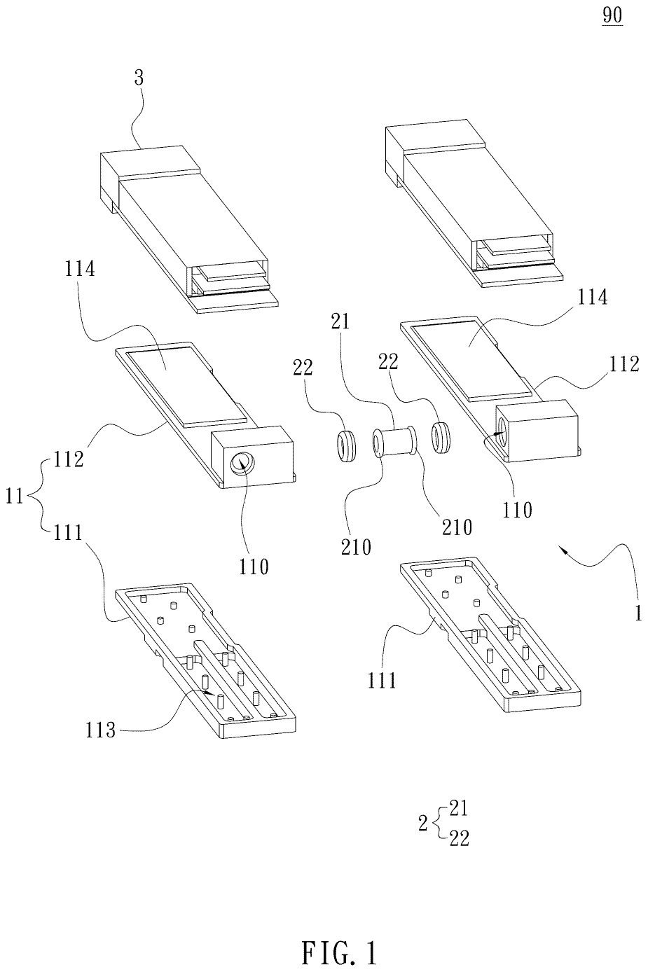

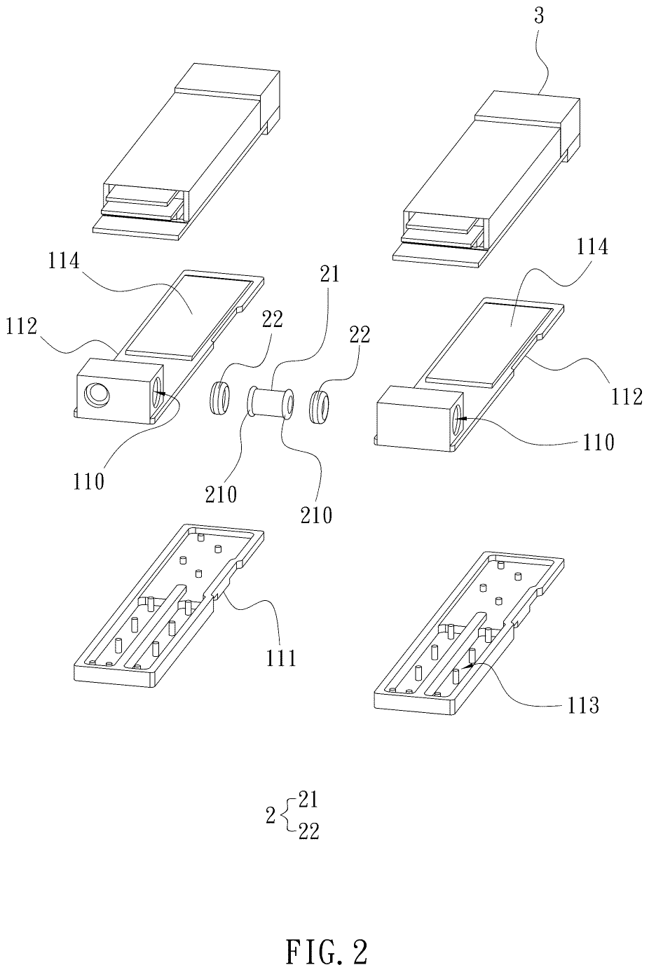

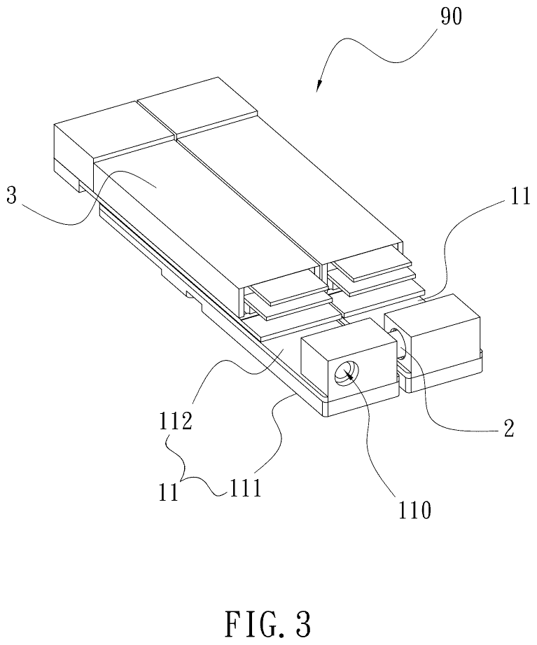

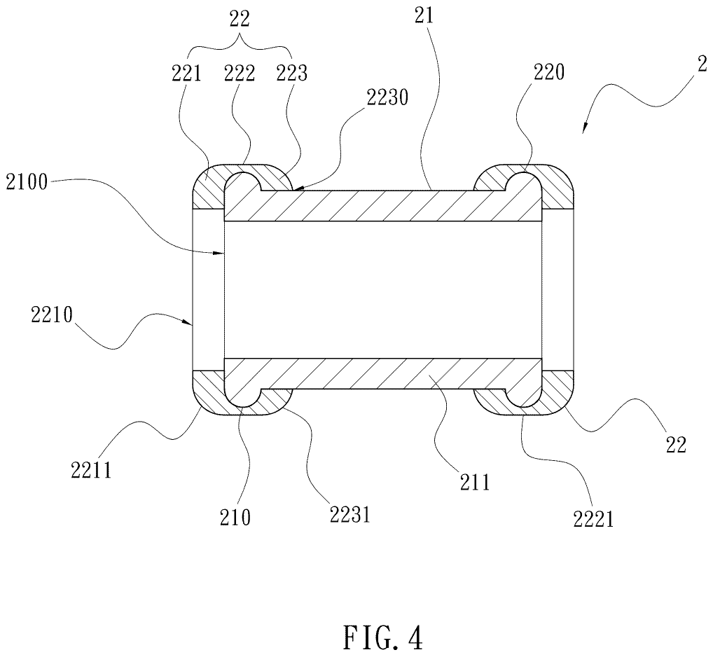

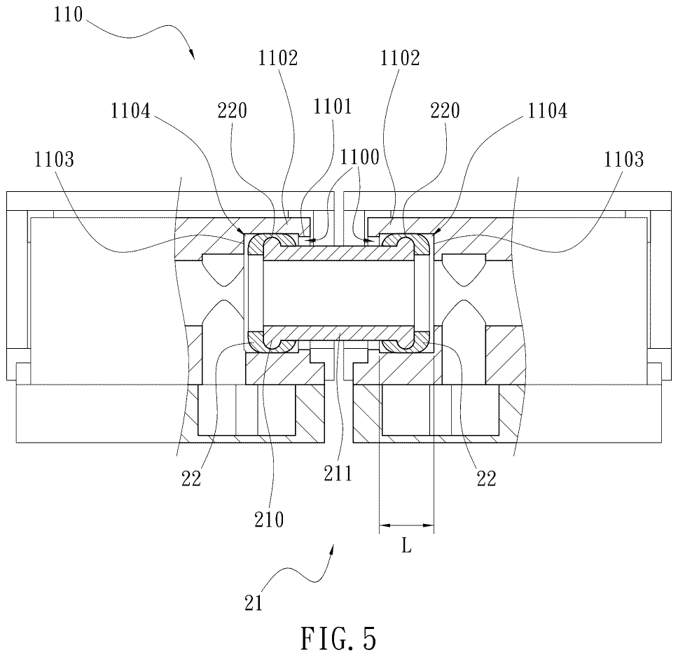

Please refer to FIGS. 1 to 5, a liquid-cooled type heat dissipation structure 90 of the present invention includes at least one liquid cooling heat dissipation module 1. The liquid cooling heat dissipation module 1 includes a plurality of liquid cooling heat dissipation elements 11 and at least one conduit unit 2, wherein the liquid cooling heat dissipation element 11 is provided with at least one port part 110 and a flow channel 113 inside. The conduit unit 2 is connected to the liquid cooling heat dissipation module 1, wherein the conduit unit 2 includes a conduit 21 and a pair of seals 22. Each of both ends of the conduit 21 has a connecting part 210 provided thereon, and each of the pair of the seals 22 is disposed on the connecting part 210 respectively. The connecting part 210 of the conduit 21 and the seal 22 provided by the conduit unit 2 are used to connect two of the port parts 110 respectively so as to connect two of the liquid cooling heat dissipation elements 11.

In this embodiment, one of the port parts 110 on one of the liquid cooling heat dissipation elements 11 in the liquid cooling heat dissipation module 1 and the other of the port parts 110 on the other of the liquid cooling heat dissipation elements 11 are laterally spaced apart from each other. The conduit 21 comprises a transverse tube body 211 and the connecting part 210 disposed at each of both ends of the transverse tube body 211. Both ends of the transverse tube body 211 are inserted into the port parts 110 through the connecting parts 210 and the seals 22 so as to position the transverse tube body 211 laterally between two of the liquid cooling heat dissipation elements 11. However, the present invention is not limited thereto. More than two port parts 110 may be disposed on one liquid cooling heat dissipation element 11 so that a plurality of liquid cooling heat dissipation elements 11 can be connected to each other through a plurality of port parts 110 and a plurality of conduits 21. In the present embodiment, two port parts 110 are provided on each liquid cooling heat dissipation element 11 so that one liquid cooling heat dissipation element 11 can be connected to the other liquid cooling heat dissipation element 11 located in front or behind through the two port parts 110 via the conduit 21.

In the present embodiment, the seal 22 is covered on the connecting parts 210, and the port part 110 has a connecting hole 1100, It can be understood that a diameter of the connecting hole 1100 is greater than or equal to a diameter of the connecting part 210 and smaller than an outer diameter of the seal 22, so that the connecting part 210 can smoothly pass through the connecting hole 1100 of the port part 110 and be inserted into the port part 110. Since the seal 22 has an elastic structure, even though the outer diameter of the seal 22 is larger than the diameter of the connecting hole 1100 of the port part 110, the seal 22 can be elastically deformed by applying pressure so that the seal 22 can be smoothly inserted into the port part 110.

In this embodiment, the connecting part 210 is a convex ring extending radially along the transverse tube body 211, and the seal 22 is an annular sealing ring, which includes an annular groove 220. The annular groove 220 can cover the convex ring to fix the annular sealing ring on the convex ring and arrange the annular sealing ring around the outer edge of the convex ring. In this embodiment, the shape of the cross-section of the convex ring is a semi-circle shape, and the shape of the cross-section of the annular groove 220 is semi-circle shape, but not limited thereto. The shape of the cross-section of the convex ring may be an ellipse shape or other arc shape, and the shape of the cross-section of the annular groove 220 may be an ellipse shape or other arc shape corresponding to the convex ring. It can be understood that the convex ring with a semicircular cross-section is convenient for inserting the connecting part 210 into the port part 110 because both the outer and inner sides of the convex ring are provided with semicircular surfaces.

Furthermore, in this embodiment, the seal 22 includes an outer ring portion 221, an inner ring portion 223, and an abutment ring portion 222 connecting the outer ring portion 221 and the inner ring portion 223. The annular groove 220 is surrounded by the abutment ring portion 222, the outer ring portion 221 and the inner ring portion 223. The outer ring portion 221 covers an outside of the convex ring, the inner ring portion 223 covers an inside of the convex ring, and the abutment ring portion 222 covers a top side of the convex ring. Further, the outer ring portion 221 has an outer opening 2210, the inner ring portion 223 has an inner opening 2230, the abutment ring portion 222 has the annular groove 2220, and the outer opening 2210 connects to the inner opening 2230 by the annular groove 2220. It can be understood that the inner opening 2230 is larger than the outer opening 2210 so that the connecting part 210 can be inserted into the annular groove 220 abutting against the abutment ring portion 222 through the larger inner opening 2230 of the inner ring portion 223 and blocked by the outer ring portion 221 having a relatively small outer opening 2210 when the seal 22 is to be sleeved on the connecting part 210 of the conduit 21.

In the present embodiment, it is worth mentioning that the outer opening 2210 of the outer ring portion 221 of the seal 22 covered on the connecting part 210 is larger than the opening 2100 of the connecting part 210. Thus, the working fluid will not be blocked by the outer ring portion 221 when flowing through the opening 2100 of the connecting part 210, and the area of the outer ring portion 221 in contact with the working fluid can be reduced, thereby reducing the degradation of the outer ring portion 221 due to the influence of the working fluid. In addition, the outer ring portion 221 has an assembly chamfer 2211, and the inner ring portion 223 has a breakaway chamfer 2231. Through the design of the assembly chamfer 2211 or the breakaway chamfer 2231, the seal 22 can be smoothly assembled and inserted into the port part 110 or disengaged from the port part 110.

In this embodiment, the port part 110 comprises a stopped wall 1101, a recessed wall 1102, a limited wall 1103, and an accommodating space 1104 surrounded by the stopped wall 1101, the recessed wall 1102 and the limited wall 1103, wherein the inner diameter of the recessed wall 1102 is less than or equal to the outer diameter of the seal 22, or the inner diameter of the recessed wall 1102 is less than or equal to the outer diameter of the abutment ring portion 222. As mentioned above, when the seal 22 is inserted into the port part 110, it will first pass through the connecting hole 1100 of the port part 110 surrounded by the stopped wall 1101, and the diameter of the connecting hole 1100 is smaller than the inner diameter of the recessed wall 1102. Therefore, the seal 22 with a larger outer diameter is compressed and deformed to pass through the connecting hole 1100 of the port part 110, and then enters the accommodating space 1104 so that the seal 22 can expand back to its original larger outer diameter. At the same time, the stopped wall 1101 can smoothly block the seal 22 so that the seal 22 is not easy to detach and exit from the port part 110. It can be understood that since the working fluid will flow in the port part 110 and the conduit 21, in order for the seal 22 to achieve a good effect of preventing fluid leakage, the inner diameter of the recessed wall 1102 should be designed to be less than or equal to the outer diameter of the seal 22, or the inner diameter of the recessed wall 1102 should be less than or equal to the outer diameter of the abutment ring portion 222 so that the seal 22 or the abutment plane 2221 on the abutment ring portion 222 can radially abut against the recessed wall 1102 without causing fluid leakage.

In this embodiment, it is worth mentioning that a thickness of the seal 22 is smaller than an axial length L of the accommodating space 1104 so that the seal 22 can slide horizontally and axially in the accommodating space 1104. Therefore, when two adjacent liquid cooling heat dissipation elements 11 float up and down, the seal 22 can slide horizontally and axially in the accommodating space 1104 and itself has compressible and deformable characteristics, thereby offsetting the displacement caused by the up and down floating of the two liquid cooling heat dissipation elements 11. In this embodiment, the seal 22 is made of elastic material, and its material may be O-ring. The conduit 21 is a circular tubular body made of metal material, and its material is iron, stainless steel, copper, aluminum, titanium, alloy or any combination of the aforementioned metal materials.

It can be understood that the outer ring portion 221 and the inner ring portion 223 of the above-mentioned seal 22 can be semicircular in design. When the liquid cooling heat dissipation element 11 is displaced, there will be an angular deformation of the seal 22 to prevent liquid leakage. In addition, the semicircular waterproof rubber ring of the seal 22 is the most basic configuration in this design. Because the seal 22 is a waterproof rubber ring with compressible characteristics, in other embodiments, the waterproof rubber ring may be configured in a plane, elliptical or other shape, which can be used in the present invention, and it can also meet the specifications. In addition, since the conduit 21 has sufficient strength, it is sufficient to support the seal 22 to make the seal 22 have good mechanical strength and support the sealing properties of the seal 22 at the same time.

Furthermore, in this embodiment, the liquid cooling heat dissipation element 11 may be a cold plate, and each liquid cooling heat dissipation element 11 includes a base 111 and an upper cover 112 disposed on the base 111. The base 111 is provided with at least one flow channel 113, which is connected to the conduit 21 through the port part 110. Moreover, each of the liquid cooling heat dissipation elements 11 is provided with a heat exchange area 114, which is located on the base 111 or the upper cover 112, and the heat exchange area 114 is provided for an electronic component to be configurated, wherein the electronic component is, for example, a heat generating component 3, and the heat generating component 3 may specifically be an optical module.

Moreover, in another embodiment of the present invention, a liquid cooling joint is provided to be connected to the port part of the liquid cooling heat dissipation element. The liquid cooling joint (cold water inlet) provides working liquid to be injected into the liquid cooling heat dissipation element through the port part. The working liquid will flow downward into the flow channel of the base so the working liquid will flow in the flow channel in the liquid cooling heat dissipation element and then flow out from the port part on the other side of the liquid cooling heat dissipation element to the next butting liquid cooling heat dissipation element. Therefore, through such an arrangement, after the working liquid enters the liquid cooling heat dissipation element, the working liquid flows into the flow channel of the liquid cooling heat dissipation element so that the working liquid can exchange heat with the heat exchange area of the liquid cooling heat dissipation element, thereby taking away the heat absorbed by the heat exchange area from the heat generating components and enabling the heat exchange area to achieve a heat dissipation effect.

Afterwards, the working liquid flows through the conduit unit and enters another liquid cooling heat dissipation element through the port part. Since the flow channel is also provided in the another liquid cooling heat dissipation element, the working liquid will flow into the flow channel in the another liquid cooling heat dissipation element and then flow out from the port part on the other side. After the working liquid enters the another liquid cooling heat dissipation element, the working liquid flows into the flow channels of the another liquid cooling heat dissipation element so that the working liquid can be quickly heat exchanged with the heat exchange area of the liquid cooling heat dissipation element to dissipate heat, thereby taking away the heat absorbed by the heat exchange area from the heat generating components and cooling the heat exchange area, and then flowing out from the port part on the other side. Therefore, through such a continuous connection arrangement, one liquid cooling heat dissipation element can be connected to the next liquid cooling heat dissipation element so that the liquid-cooled type heat dissipation structure can be continuously expanded.

In summary, the present invention uses a liquid-cooled type heat dissipation structure to connect the liquid cooling heat dissipation module through the conduit unit so that the working liquid flows into one liquid cooling heat dissipation element and flows to another liquid cooling heat dissipation module through the conduit unit. The working liquid flows in the liquid cooling heat dissipation element, and the heat energy of the optical module is taken away by the working liquid to achieve the purpose of heat dissipation. Therefore, the present invention can provide liquid cooling heat dissipation for the optical module of the switch in a small or limited space such as a cabinet (such as a data center) by using the liquid-cooled type heat dissipation structure.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A liquid-cooled type heat dissipation structure, comprising:
a liquid cooling heat dissipation module, wherein the liquid cooling heat dissipation module comprises a plurality of liquid cooling heat dissipation elements, and each of the liquid cooling heat dissipation elements is provided with at least one port part; and
a conduit unit connected to two of the liquid cooling heat dissipation elements of the liquid cooling heat dissipation module, wherein the conduit unit comprises a conduit and a pair of seals; each of both ends of the conduit having a connecting part provided thereon, and each of the pair of the seals being disposed on the connecting part; the connecting part of the conduit and the seal provided by the conduit unit being used to connect two of the port parts respectively so as to connect two of the liquid cooling heat dissipation elements.

2. The liquid-cooled type heat dissipation structure as claimed in claim 1, wherein one of the port parts on one of the liquid cooling heat dissipation elements and the other of the port parts on the other of the liquid cooling heat dissipation elements are laterally spaced apart from each other; the conduit comprising a transverse tube body and the connecting part disposed at each of both ends of the transverse tube body; both ends of the transverse tube body being inserted into the port parts through the connecting parts and the seals so as to position the transverse tube body laterally between two of the liquid cooling dissipation elements.

3. The liquid-cooled type heat dissipation structure as claimed in claim 1, wherein the seal covers the connecting part, the port part has a connecting hole, and a diameter of the connecting hole is greater than or equal to a diameter of the connecting part and smaller than an outer diameter of the seal.

4. The liquid-cooled type heat dissipation structure as claimed in claim 1, wherein the connecting part is a convex ring, the seal comprises an annular groove, and the annular groove covers the convex ring to fix the seal on the convex ring.

5. The liquid-cooled type heat dissipation structure as claimed in claim 4, wherein the seal comprises an outer ring portion, an inner ring portion, and an abutment ring portion connecting the outer ring portion and the inner ring portion; the annular groove being surrounded by the abutment ring portion, the outer ring portion and the inner ring portion; the outer ring portion covering an outside of the convex ring, the inner ring portion covering an inside of the convex ring, and the abutment ring portion covering a top side of the convex ring.

6. The liquid-cooled type heat dissipation structure as claimed in claim 5, wherein the outer ring portion has an outer opening, the inner ring portion has an inner opening, the abutment ring portion has the annular groove, and the annular groove connects the outer opening and the inner opening; the connecting part of the conduit has an opening, the outer opening is larger than the opening, and the inner opening is larger than the outer opening.

7. The liquid-cooled type heat dissipation structure as claimed in claim 5, wherein the port part comprises a stopped wall, a recessed wall, a limited wall, and an accommodating space surrounded by the stopped wall, the recessed wall and the limited wall, and an inner diameter of the recessed wall is smaller than or equal to the outer diameter of the abutment ring portion.

8. The liquid-cooled type heat dissipation structure as claimed in claim 7, wherein a thickness of the seal is less than an axial length of the accommodating space.

9. The liquid-cooled type heat dissipation structure as claimed in claim 7, wherein the outer ring portion has an assembly chamfer, the inner ring portion has a breakaway chamfer, and the abutment ring portion has an abutment plane that abuts against the recessed wall.

10. The liquid-cooled type heat dissipation structure as claimed in claim 1, wherein each of the liquid cooling dissipation elements comprises a base and an upper cover disposed on the base; the base is provided with at least one flow channel connected to the conduit through the port part; each of the liquid cooling heat dissipation elements is provided with a heat exchange area located on the base or the upper cover, and the heat exchange area is provided for an electronic component to be configurated.
